(19) United States
(12) Patent Application Publication
(10) Pub. No.: US 2009/0298259 A1
(43) Pub. Date: Dec. 3, 2009

(54) Method for transferring one-dimensional micro/nanostructure

(76) Inventors: Ching-Fuh Ling, Taipei (TW); Shu-Chia Shiu, Taipei (TW); Chieh-Yu Hsiao, Taipei (TW); Meng-Yueh Liu, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/232,627

(22) Filed: Sep. 22, 2008

(30) Foreign Application Priority Data
May 28, 2008 (TW) 097119718

(51) Int. Cl. H01L 21/30

(52) U.S. Cl. 438/458; 257/E21.237

(57) ABSTRACT

As the conventional nanowire technology has many restrictions, the present invention discloses a method for transferring a one-dimensional micro/nanostructure to diversify the fabrication and application of nanocomponents, wherein a micro/nanostructure having formed on one substrate can be arbitrarily transferred to another substrate, whereby a micro/nanostructure can be integrated with different substrates.

### BACKGROUND OF THE INVENTION

1. Field of the Invention

The present invention relates to a one-dimensional micro/nanostructure, particularly to a method for transferring a one-dimensional micro/nanostructure.

2. Description of the Related Art

With the development of nanometric technology, many researches are dedicated to miniaturizing materials and components. The one-dimensional micro/nanostructures refer to linear/columnar micron/nanometric-scale materials, including nanowires. Nanowires are emerging materials in the fields of electronics and optoelectronics, such as integrated circuits, organic solar cells, field effect transistors, and gas detectors. A nanowire is characterized in its very great length-width ratio. Growing a nanowire means inhibiting the growth in two directions (such as x direction and y direction) and facilitating the growth in the third direct (z direction). Because of nanometric size, the quantum effect of nanowires brings about many amazing physical and chemical properties in comparison with bulk materials.

No matter in a liquid, solid or gas phase, growing a nanowire includes two steps: nucleation and growth. When atoms or molecules are supersaturated in a solution, the atoms or molecules will cluster to nucleate. After nucleation, the atoms or molecules are apt to adhere to the nuclei. From the viewpoint of thermodynamics, a nanowire forms because stacking atoms or molecules in a specified direction has a greater energy drop.

From the viewpoint of the reaction environment, methods for forming nanowires may be categorized into soft approaches and hard approaches. Hard approaches refer to the methods needing an unusual environment, such as high temperature, high vacuum or a hard template. The VLS (Vapor-Liquid-Solid) method proposed by Wager and Ellis in 1964 is a common method to grow III-V group or semiconductor nanowires. In the VSL method, a metallic catalyst is used as a medium to deliver vapor-phase atoms. The atoms diffuse through the liquid metal to the bottom substrate where the atoms stack to form nanowires. In the VLS method, a specified material has to be grown on a specified substrate (usually a substrate made of a similar material) lest crystalline mismatch occur. In 2007, Stelzner et al. grew silicon nanowires on a silicon substrate via different metals, such as gallium, indium, aluminum and gold. In 2005, Mohan et al. used an e-beam lithography technology to grow an indium-phosphide nanowire on an indium-phosphide substrate. Compared with the hard approaches, the soft approaches use a temperate environment of an ambient temperature, a normal pressure and a liquid solution. The hydrothermal method, SLS (Solution-Liquid-Solid) method, biochemical synthesis method, and surfactant method are the frequently used methods among the soft approaches at present. However, the nanowires fabricated with the latter three methods are randomly dispersed because the nucleation locations are arbitrary. The hydrothermal method is the popular method to fabricate ordered nanowires; especially, zinc oxide is the best example of epitaxy. The etching method for fabricating nanowires is a method that cannot be categorized into the abovementioned approaches. In the etching method, nanoparticles are used as the mask for etching a bulk material, and a RIE (Reactive Ion Etching) machine or an etching liquid is used to etch away the unmasked areas. Via controlling the etching time and etching gas (or liquid), the etching method can attain nanowires with different lengths and widths. The nanowires fabricated with the etching method, such as silicon nanowires, are neatly arranged and almost vertical to the substrate. However, the etching method has to carefully select the etching gas (or liquid) for different materials. In 2005, Chang et al. fabricated gallium-nitride nanowires via coating a nickel layer as the mask on a gallium-nitride bulk material and etching the gallium-nitride bulk material with a RIE machine using chlorine gas and argon gas.

The VLS method and the hydrothermal method are the bottom-up methods and need a specific substrate or a specific seed layer. Strictly to say, the molding method does not grow nanowires but fills material into a mold to form nanowires; the mold is used as the substrate herein. The etching method etches the bulk material to form nanowires, and the bulk material is exactly the material of the nanowires. In the existing technologies, a specified nanowire needs a specified substrate. In other words, a nanowire cannot form on an arbitrary substrate. For example, a high-quality Ill-V group nanowire (such a GaAs, GaAlAs, InP, or InGaAsP nanowire) is hard to grow on a silicon substrate or a glass substrate. The abovementioned problem greatly restricts the application of nanowires.

### SUMMARY OF THE INVENTION

The primary objective of the present invention is to provide a method for transferring a one-dimensional micro/nanostructure, whereby a one-dimensional micro/nanostructure can be transferred from one substrate to another substrate, and whereby a one-dimensional micro/nanostructure can be integrated with different substrates, and whereby diverse nanowires can be developed and fabricated, and whereby the conventional problems are overcome.

To achieve the abovementioned objective, the present invention proposes a method for transferring a one-dimensional micro/nanostructure, which comprises steps: providing a first substrate having a plurality of one-dimensional micro/nanostructures; providing a second substrate; coating a first curable adhesive on the second substrate; inserting the one-dimensional micro/nanostructures on the first substrate into the first curable adhesive on the second substrate; curing the first curable adhesive; separating the one-dimensional micro/nanostructures from the first substrate and transferring the one-dimensional micro/nanostructures to the second substrate.

In the present invention, the one-dimensional micro/nanostructures can be further transferred to a third substrate in the same method. Similarly, the one-dimensional micro/nanostructures can also be transferred to a fourth substrate in the same method.

Below, the embodiments are described in detail in cooperation with the drawings to make easily understood the objectives, characteristics and efficacies of the present invention.

### BRIEF DESCRIPTION OF THE DRAWINGS

FIGS. 1A-1I are diagrams schematically showing a method for transferring a one-dimensional micro/nanostructure according to one embodiment of the present invention;

FIGS. 2A-2G are diagrams schematically showing that a first substrate has an additional selectively-etched layer according to another embodiment of the present invention;

FIGS. 3A-3E are diagrams schematically showing a method for transferring a one-dimensional micro/nanostructure according to yet another embodiment of the present invention;

FIGS. 4A-4E are diagrams schematically showing that one-dimensional micro/nanostructures are transferred from a second substrate to a third substrate according to still another embodiment of the present invention;

FIGS. 5A-5D are diagrams schematically showing that one-dimensional micro/nanostructures are transferred from a second substrate to a third substrate according to a further embodiment of the present invention;

FIGS. 6A-6E are diagrams schematically showing that one-dimensional micro/nanostructures are transferred to a fourth substrate according to a yet further embodiment of the present invention;

FIGS. 7A-7D are diagrams schematically showing that one-dimensional micro/nanostructures are transferred from a second substrate to a third substrate according to a still further embodiment of the present invention; and

FIGS. 8A-8E are diagrams schematically showing that one-dimensional micro/nanostructures are transferred from a second substrate to a fourth substrate according to a still yet further embodiment of the present invention.

### DETAILED DESCRIPTION OF THE INVENTION

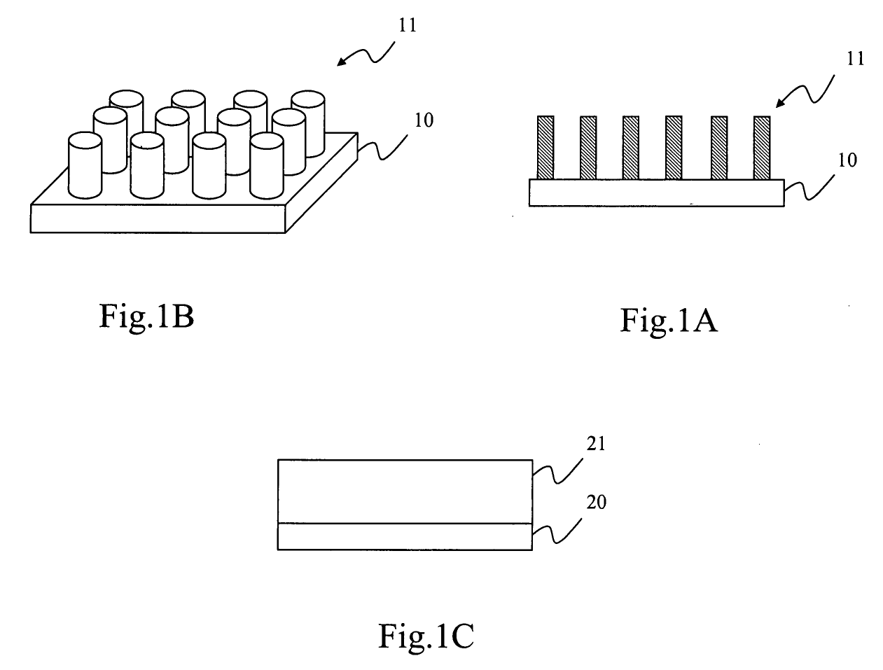

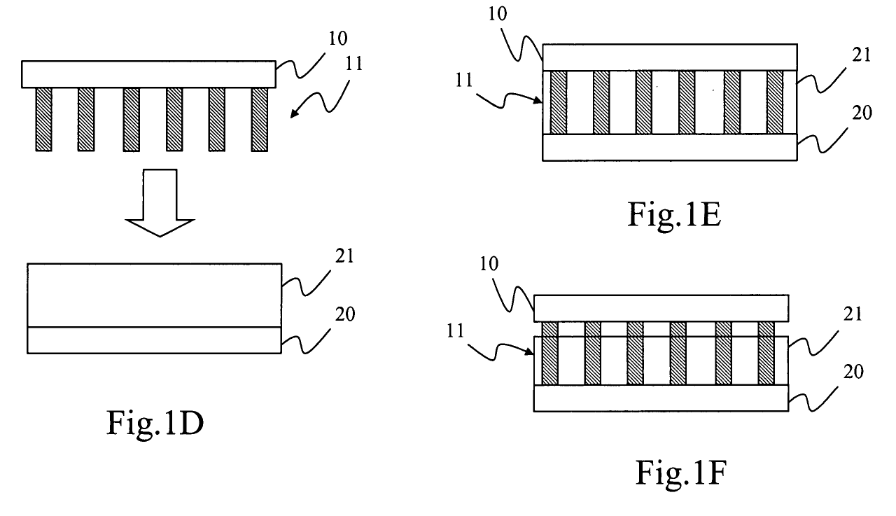

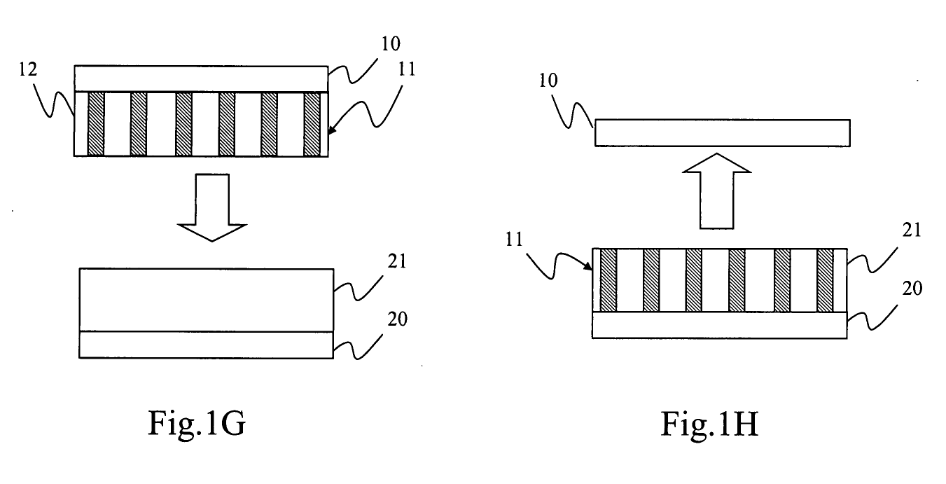

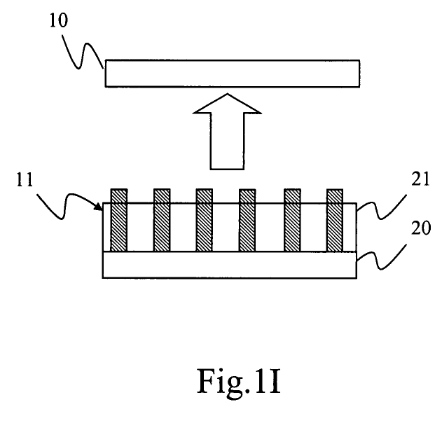

Refer to FIGS. 1A-1I for a method for transferring a one-dimensional micro/nanostructure according to one embodiment of the present invention.

In this embodiment, a first substrate 10 is provided firstly, and then a plurality of one-dimensional micro/nanostructures 11 is formed on the first substrate 10, as shown in FIG. 1A. The one-dimensional micro/nanostructures 11 are micron/nanometric wire-like/column-like structures vertical to the substrate 10, and the one-dimensional micro/nanostructure 11 has a sectional width of between 1 nm and 1000 μm, and a height of between 0.3 μm and 60 μm, as shown in FIG. 1B. The nanowires or nanocolumns are made of a semiconductor material or another material, such as silicon, germanium, gallium arsenide, indium phosphide, germanium phosphide, antimony selenide, indium gallium nitride, a binary compound semiconductor, a ternary compound semiconductor, or a quaternary compound semiconductor. The one-dimensional micro/nanostructures 11 are formed on the first substrate 11 with a CVD (Chemical Vapor Deposition) method, an epitaxial method, a chemical etching method, a dry etching method, or another method.

The material of the first substrate 10 is dependent on the material of the one-dimensional micro/nanostructures 11 and may be a semiconductor, a metal, or an insulating material. The material of a second substrate 20, which is to be mentioned below, is dependent on the practical application and may be a plastic, a metal, a semiconductor, a ceramic, a transparent material, or a glass coated with a transparent conductive layer.

Next, a second substrate 20 is provided, and a first curable adhesive 21 is applied onto the second substrate 20, as shown in FIG. 1C. The first curable adhesive 21 is a solidifiable liquid or gel, such as a sol, a gel, a polymeric material, a wax, SOG (Spin-On Glass), PMMA (polymethylmethacrylate), or, P3HT (poly(3-hexylthiophene)). If the second substrate 20 is made of a heat-resistant material, the first curable adhesive 21 may also adopt a molten metal. Next, the one-dimensional micro/nanostructures 11 of the first substrate 10 is inserted into the first curable adhesive 21 of the second substrate 20, as shown in FIG. 1D. The one-dimensional micro/nanostructures 11 may be completely submerged into the first curable adhesive 21, as shown in FIG. 1E. Alternatively, the one-dimensional micro/nanostructures 11 may be only partially submerged into the first curable adhesive 21, as shown in FIG. 1F.

Considering the nanostructures are hard to be directly inserted into the first curable adhesive 21, a second curable adhesive 12 is applied onto the one-dimensional micro/nanostructures 11 on the first substrate 10, and then let the second curable adhesive 12 gradually permeate into the gaps of the one-dimensional micro/nanostructures 11, as shown in FIG. 1G. At the same time, the first curable adhesive 21 is also applied onto the second substrate 20. Then, let the second curable adhesive 12 on the first substrate 10 insert into the first curable adhesive 21 on the second substrate 20. In the present invention, the materials of the first curable adhesive 21 and the second curable adhesive 12 may be identical or different.

Next, the first curable adhesive 21 is cured to bond the second substrate 20 to the first substrate 10. At this time, the one-dimensional micro/nanostructures 11 are vertically stuck to the first substrate 10 and secured by the first curable adhesive 21. Next, the one-dimensional micro/nanostructures 11 are separated from the first substrate 10 and transferred to the second substrate 20, and the one-dimensional micro/nanostructures 11 are maintained about vertical to the second substrate 20, as shown in FIG. 1H and FIG. 1I. The one-dimensional micro/nanostructures 11 are separated from the first substrate 10 via various methods. For example, the one-dimensional micro/nanostructures 11 is separated from the first substrate 10 via ultrasonic vibration, knocking the lateral of the first substrate 10, slightly knocking the surface, or pulling up the first substrate 10 with a pump. If the one-dimensional micro/nanostructures 11 are well stuck to the first curable adhesive 21, the one-dimensional micro/nanostructures 11 can be detached from the first substrate 10 via directly lifting off the first substrate 10. The first substrate 10 may also be removed with a chemical etching method.

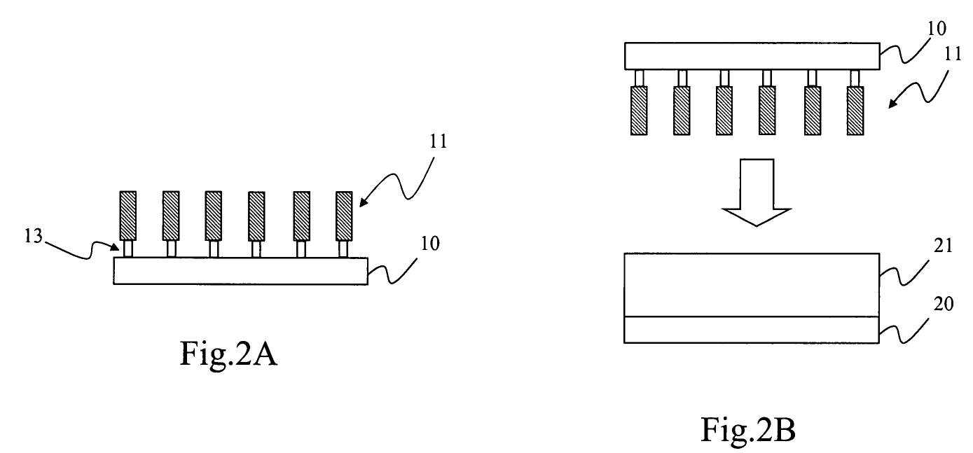

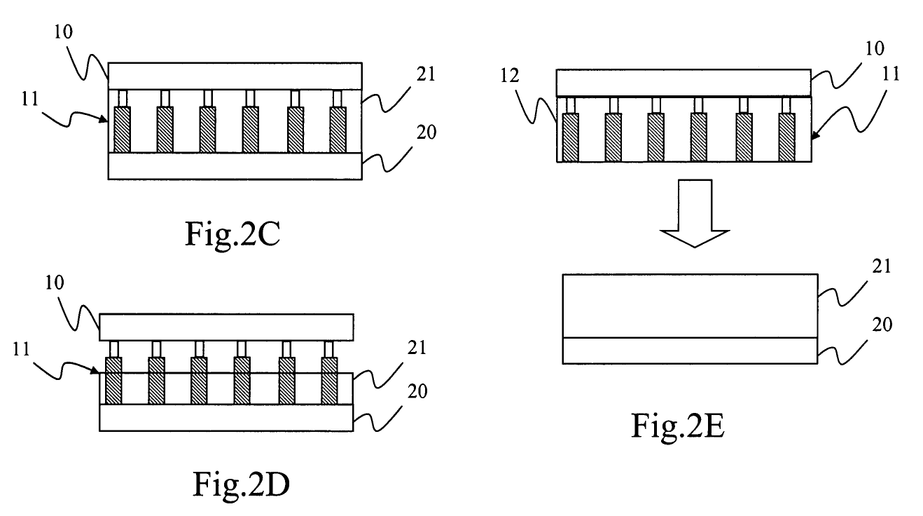

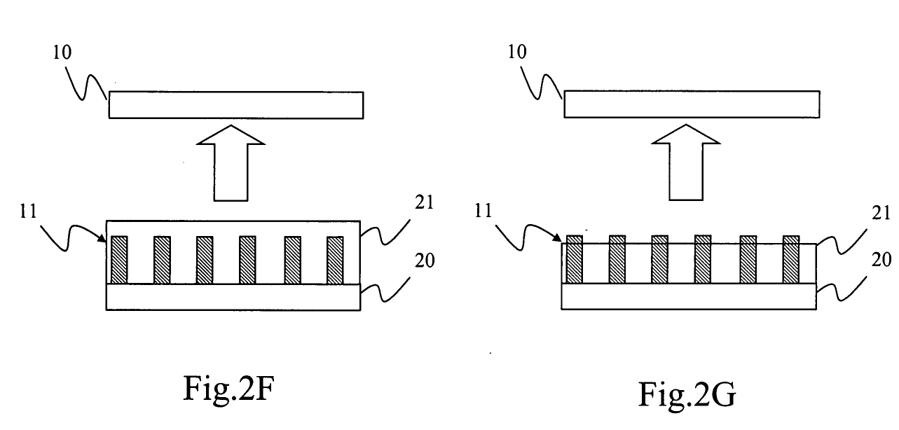

Refer to FIGS. 2A-2G for another embodiment of the present invention. If the one-dimensional micro/nanostructures 11 are too tough to be separated from the first substrate 10 with ultrasonic vibration or knocking, a selectively-etched layer 13 is formed in between the first substrate 10 and the one-dimensional micro/nanostructures 11, as shown in FIG. 2A. Refer to FIGS. 2B-2G. In this embodiment, the one-dimensional micro/nanostructures 11 are transferred with the same steps described above. The first curable adhesive 21 is applied onto the second substrate 20. Next, the one-dimensional micro/nanostructures 11 on the first substrate 10 are inserted into the first curable adhesive 21 on the second substrate 20, as shown in FIG. 2B. The one-dimensional micro/nanostructures 11 may be completely submerged into the first curable adhesive 21, as shown in FIG. 2C. Alternatively, the one-dimensional micro/nanostructures 11 may only be partially submerged into the first curable adhesive 21, as shown in FIG. 2D. Similarly, the second curable adhesive 12 is applied onto the one-dimensional micro/nanostructures 11 of the first substrate 10, and let the second curable adhesive 12 gradually permeate into the gaps of the one-dimensional micro/nanostructures 11, as shown in FIG. 2E. Then, let first substrate 10 having the one-dimensional micro/nanostructures 11 contact the second substrate 20 coated with the first curable adhesive 21.

Next, the first curable adhesive 21 is cured to bond the second substrate 20 to the first substrate 10, and the one-dimensional micro/nanostructures 11 are thus vertically stuck to the second substrate 20 by the first curable adhesive 21. Next, the selectively-etched layer 13 is etched away with a chemical etching method or a dry etching method. Thus, the one-dimensional micro/nanostructures 11 are separated from the first substrate 10 without violently damaging the first substrate 10 and the one-dimensional micro/nanostructures 11, as shown in FIG. 2F or FIG. 2G. Naturally, the other methods mentioned above may also be used to separate the one-dimensional micro/nanostructures 11 from the first substrate 10.

The one-dimensional micro/nanostructures 11 transferred to the second substrate 20 are then used to fabricate the desired components. For example, the nanostructures are made of a III-V group light emitting material, and the second substrate is a Si substrate, and thus is realized the integration of optoelectronic components and silicon electronic components.

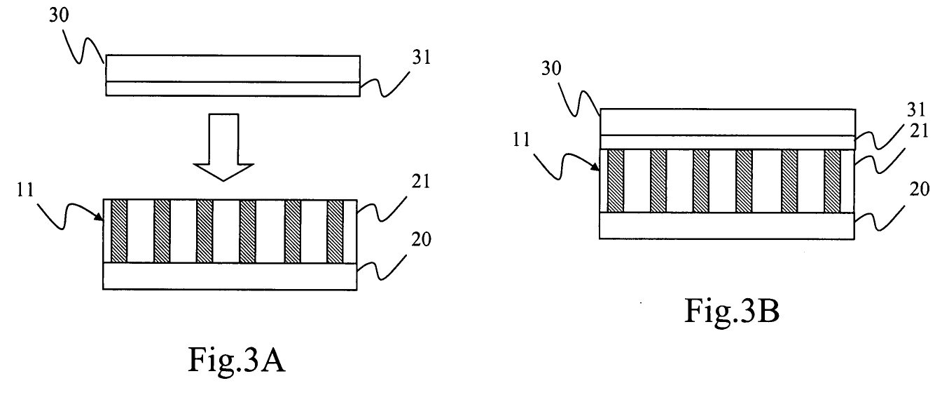

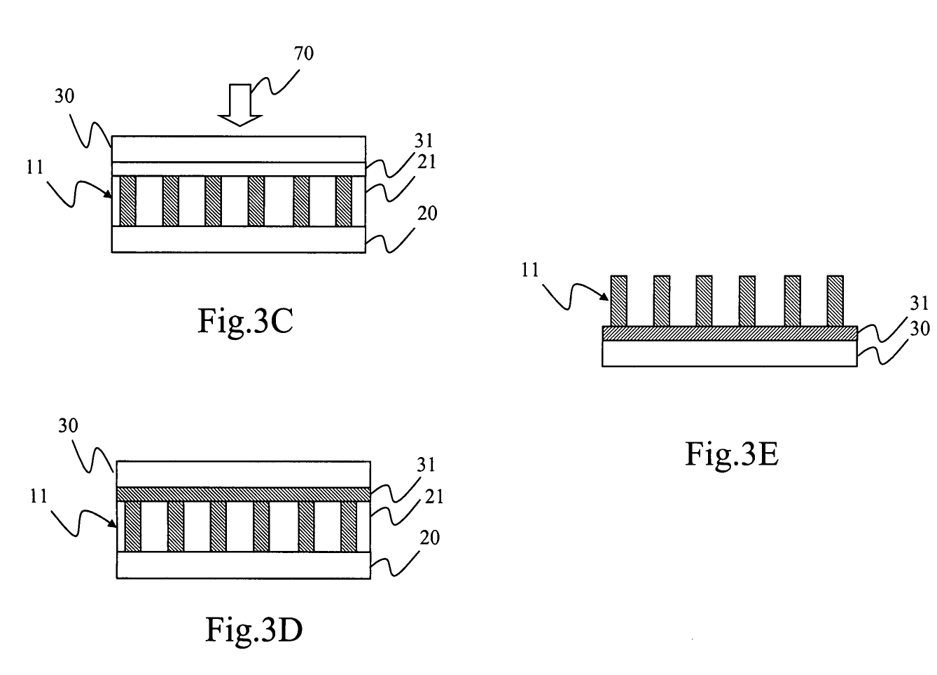

Refer to FIGS. 3A-3E for yet another embodiment of the present invention. In this embodiment, the one-dimensional micro/nanostructures 11 on the second substrate 20 are further transferred to a third substrate 30.

Refer to FIG. 3A. Firstly, a layer of welding material 31 is coated on a third substrate 30. The welding material 31 can be fused together with the one-dimensional micro/nanostructures 11. For example, if the one-dimensional micro/nanostructures 11 are made of a silicon material, silicon will be adopted as the welding material 31. The material of the third substrate may be a plastic, a metal, a semiconductor, a ceramic, a transparent material, or a glass coated with a transparent conductive layer.

Refer to FIG. 3B. Next, let the welding material 31 on the third substrate 30 contact the one-dimensional micro/nanostructures 11 on the second substrate 20. Refer to FIG. 3C. Next, the welding material 31 and the third substrate 30 are heated to a temperature, at which the welding material 31 and the portion of the one-dimensional micro/nanostructures 11 contacting the welding material 31 are melted with the third substrate 30 maintaining at a solid state. Thus, the one-dimensional micro/nanostructures 11 and the welding material 31 are fused together, as shown in FIG. 3D. Then, let the molten welding material 31 and the molten one-dimensional micro/nanostructures 11 cool down and solidify. Thus are joined together the one-dimensional micro/nanostructures 11 and the third substrate 30.

As shown in FIG. 3C, an intense laser light 70 passes through the third substrate 30 and illuminates the welding material 31 and the one-dimensional micro/nanostructures 11 contacting the welding material 31, wherein the laser light 70 is controlled to such an intensity that the welding material 31 and the portion of the one-dimensional micro/nanostructures 11 contacting the welding material 31 are melted with the third substrate 30 maintaining at a solid state. Refer to FIG. 3E. Then, the first curable adhesive 21 of the second substrate 20 is removed with a solvent, and the one-dimensional micro/nanostructures 11 is separated from the second substrate 20 and transferred to the third substrate 30.

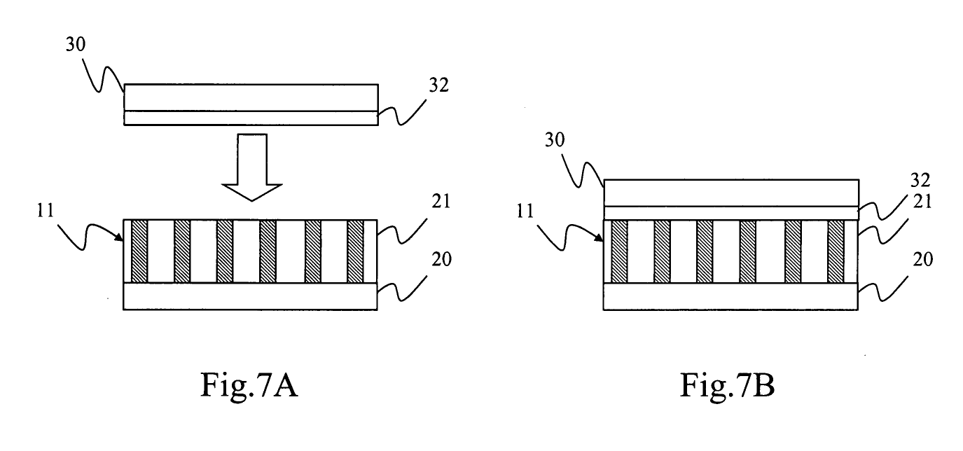

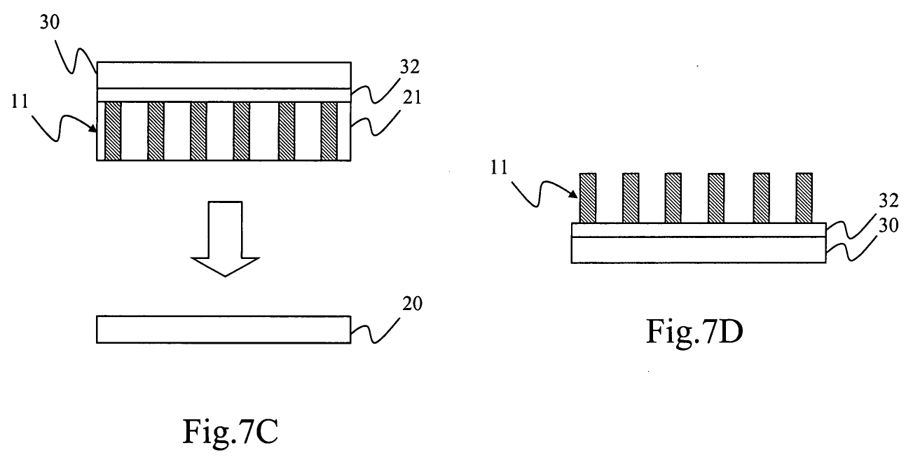

Refer to FIGS. 7A-7D for a still further embodiment of the present invention, wherein one-dimensional micro/nanostructures are transferred from a second substrate to a third substrate. In this embodiment, the transfer may also use the same method for the transfer from the first substrate to the second substrate. Firstly, a third curable adhesive 32 is applied onto a third substrate 30, as shown in FIG. 7A. Next, let the one-dimensional micro/nanostructures 11 on the second substrate 20 contact the third curable adhesive 32 on the third substrate 30, as shown in FIG. 7B. Next, the one-dimensional micro/nanostructures 11 are separated from the second substrate 20 via ultrasonic vibration, slight knockings, pump suction, chemical etching, or even directly lifting off the second substrate 20, as shown in FIG. 7C. Then, the first curable adhesive 21 is removed with a solvent; thus, the one-dimensional micro/nanostructures 11 are transferred to the third substrate 30, as shown in FIG. 7D.

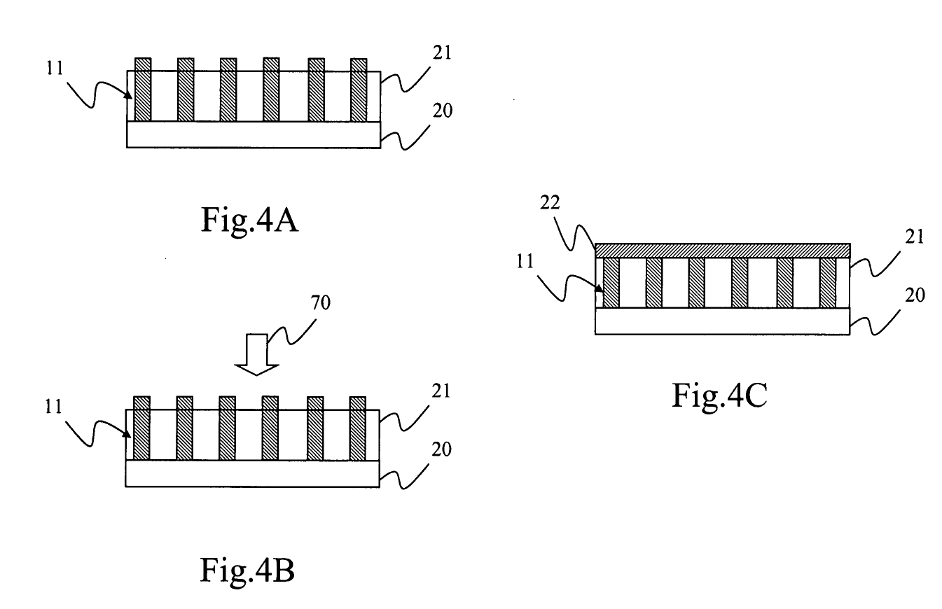

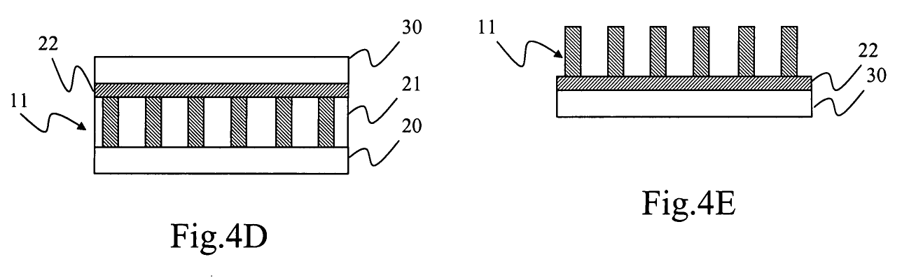

Refer to FIGS. 4A-4E for still another embodiment of the present invention, wherein the one-dimensional micro/nanostructures 11 are transferred from a second substrate 20 to a third substrate 30.

Firstly, a portion of the first curable adhesive 21 is removed with a chemical etching method or a dry etching method to partially reveal the one-dimensional micro/nanostructures 11, as shown in FIG. 4A. Alternatively, if the one-dimensional micro/nanostructures 11 on the second substrate 20 have been partially revealed, the second substrate 20 is directly adopted. Next, the revealed one-dimensional micro/nanostructures 11 are illuminated with an intense laser light 70 having such an intensity that the tops of the one-dimensional micro/nanostructures 11 are melted to form a film 22 covering the first curable adhesive 21, as shown in FIG. 4B and FIG. 4C. Then, let the film 22 cool down and solidify. As the film 22 and the one-dimensional micro/nanostructures 11 are of an identical material, they can be fused together easily. Next, as shown in FIG. 4D, the film 22 is bonded to a third substrate 30 with a van der walls force technology, a silicon-glass anodic bonding technology, a liquid-solid alloying bonding technology, or a common LCD (Liquid Crystal Display) bonding technology, such as TAB (Tape Automated Bonding), ACF (Anisotropic Conductive Film), COG (Chip On Glass), COF (Chip On Film), etc. Then, the cured first curable adhesive 21 is removed with a solvent to separate the one-dimensional micro/nanostructures 11 from the second substrate 20; thus, the one-dimensional micro/nanostructures 11 is transferred to the third substrate 30, as shown in FIG. 4E.

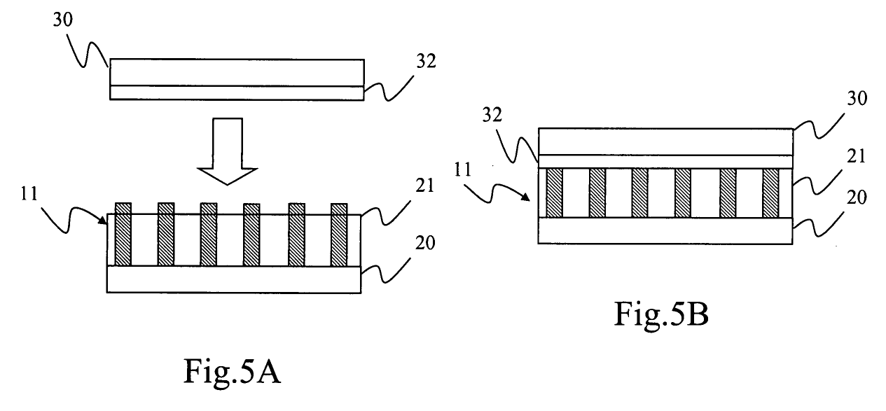

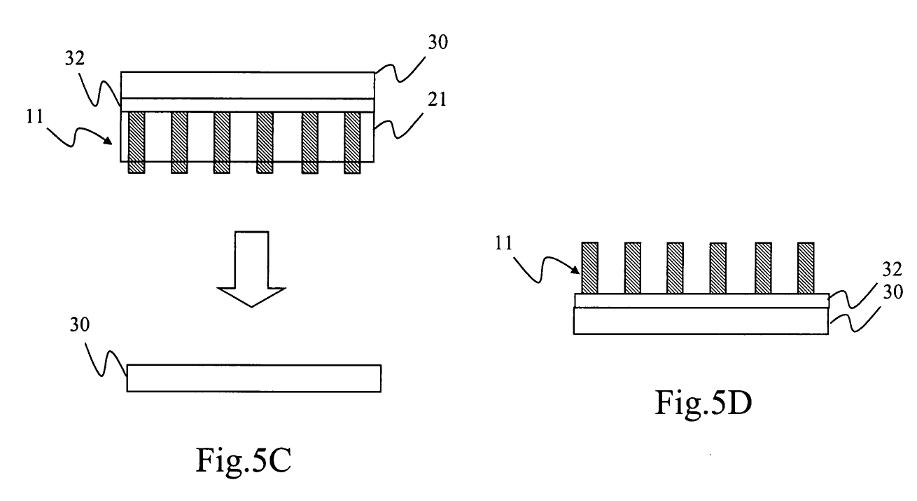

Refer to FIGS. 5A-5D for a further embodiment of the present invention, wherein one-dimensional micro/nanostructures are transferred from a second substrate to a third substrate. In this embodiment, the transfer may also use the same method for the transfer from the first substrate to the second substrate. Firstly, a third curable adhesive 32 is applied onto a third substrate 30, as shown in FIG. 5A. Next, the one-dimensional micro/nanostructures 11 on the second substrate 20 is inserted into the third curable adhesive 32 on the third substrate 30, as shown in FIG. 5B. Next, the third curable adhesive 32 is cured, and the one-dimensional micro/nanostructures 11 is separated from the second substrate 20 via ultrasonic vibration, slight knockings, pump suction, chemical etching, or even directly lifting off the second substrate 20, as shown in FIG. 5C. Then, the first curable adhesive 21 is removed with a solvent; thus, the one-dimensional micro/nanostructures 11 are transferred to the third substrate 30, as shown in FIG. 5D.

Via the abovementioned methods, microstructures and submicrostructures can also be transferred from a first substrate to another substrate. The microstructure or submicrostructure is made of a semiconductor material or another material, such as silicon, germanium, gallium arsenide, indium phosphide, germanium phosphide, antimony selenide, indium gallium nitride, a binary compound semiconductor, a ternary compound semiconductor, or a quaternary compound semiconductor. The nanostructures (such as nanowires and nanocolumns), microstructures and submicrostructures are fabricated via etching a well crystallized chip or via a high-quality epitaxial process. Therefore, the nanostructures, microstructures and submicrostructures have the advantages of crystalline semiconductors. Further, after the nanostructures are separated from the substrate, the substrate can be used again. Therefore, the present invention will not consume too much semiconductor material.

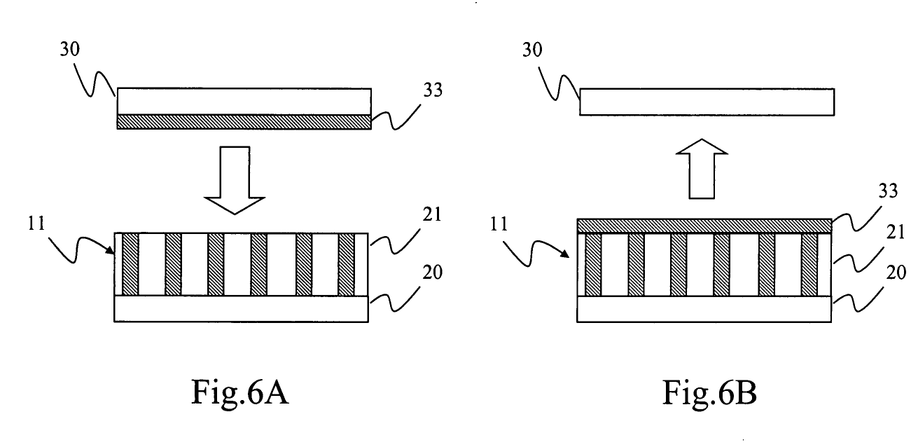

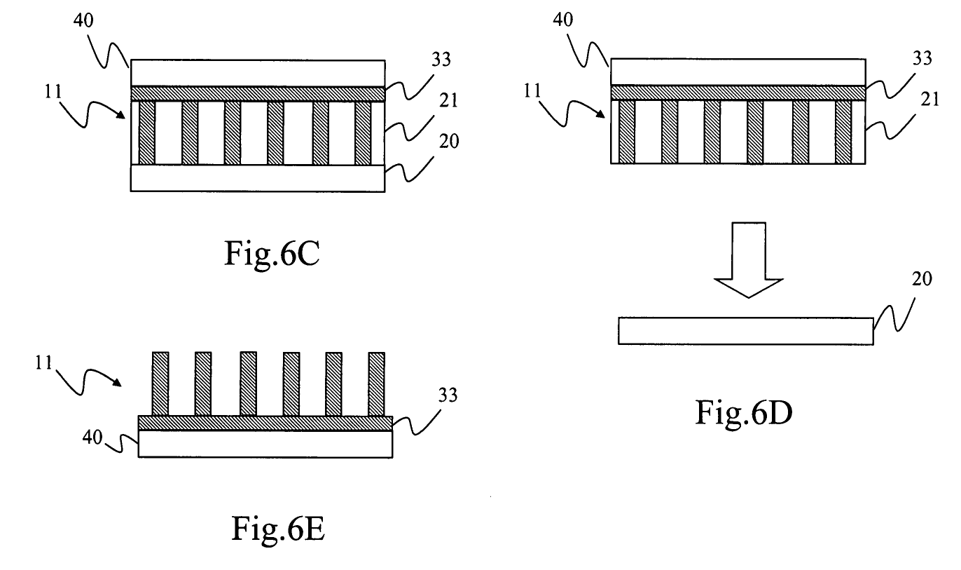

Refer to FIGS. 6A-6E for a yet further embodiment of the present invention, wherein one-dimensional micro/nanostructures are transferred to a fourth substrate.

Firstly, a welding material film 33 is formed on a third substrate 30, wherein the welding material film 33 and the one-dimensional micro/nanostructures 11 can be fused together. The welding material film 33 is melted by heating, and the one-dimensional micro/nanostructures 11 on the second substrate 20 are inserted into the molten welding material film 33 on the third substrate 30, as shown in FIG. 6A. After the welding material film 33 cools down and solidifies, the third substrate 30 is separated from the welding material film 33, and the welding material film 33 is thus bonded to the one-dimensional micro/nanostructures 11, as shown in FIG. 6B. Next, a fourth substrate 40 is bonded to the welding material film 33, as shown in FIG. 6C. Next, the one-dimensional micro/nanostructures 11 are separated from the second substrate 20, as shown in FIG. 6D. Then, the first curable adhesive 21 is removed with a solvent, and the one-dimensional micro/nanostructures 11 are thus transferred to the fourth substrate 40, as shown in FIG. 6E.

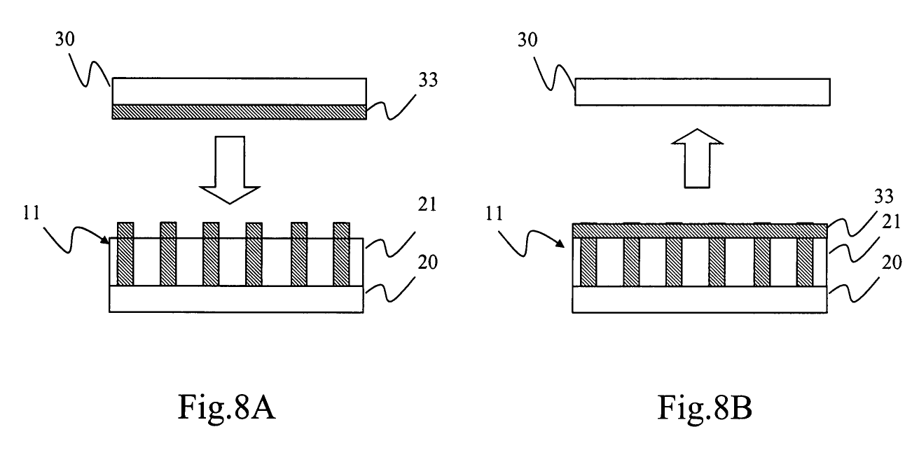

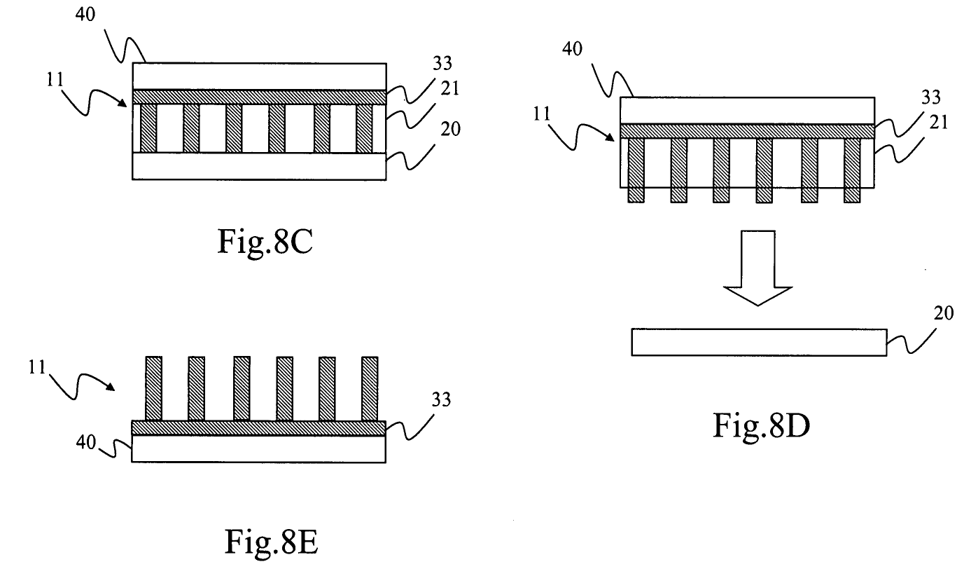

Refer to FIGS. 8A-8E for a still yet further embodiment of the present invention, wherein one-dimensional micro/nanostructures are transferred from a second substrate to a fourth substrate. The partially revealed one-dimensional micro/nanostructures 11 may also be transferred to a fourth substrate. Similarly to the abovementioned steps, a welding material film 33 is formed on a third substrate 30 and melted by heating, and the one-dimensional micro/nanostructures 11 on the second substrate 20 are inserted into the molten welding material film 33 on the third substrate 30, as shown in FIG. 8A. After the welding material film 33 cools down and solidifies, the third substrate 30 is separated from the welding material film 33, and the welding material film 33 is thus bonded to the one-dimensional micro/nanostructures 11, as shown in FIG. 8B. Next, a fourth substrate 40 is bonded to the welding material film 33, as shown in FIG. 8C. Next, the second substrate 20 is separated from the one-dimensional micro/nanostructures 11, as shown in FIG. 8D. Then, the first curable adhesive 21 is removed with a solvent, and the one-dimensional micro/nanostructures 11 are thus transferred to the fourth substrate 40, as shown in FIG. 8E.

The welding material film 33 can be bonded to the one-dimensional micro/nanostructures 11 with a laser light 70. After the welding material film 33 is formed on the third substrate 30, let the one-dimensional micro/nanostructures 11 contact the welding material film 33 on the third substrate 30, the welding material film 33 and the tops of the one-dimensional micro/nanostructures 11 are melted by an intense laser light 70. Thus is formed a film 33 covering the first curable adhesive 21. After the film 22 cools down and solidifies, the film 33 and one-dimensional micro/nanostructures 11 are fused together. Then, the film 33 is separated from the third substrate 30 and only boned to the one-dimensional micro/nanostructures 11.

Via the abovementioned methods, the epitaxial semiconductor structures emitting an infrared ray having a wavelength of 1.3-1.6 μm can be placed on a silicon substrate. Thereby, an optical communication light source and IC can be integrated in an identical chip. Also, the epitaxial semiconductor structures for waveband detection can be placed on a silicon substrate. Thereby, an optical communication detector and IC can be integrated in an identical chip, which will greatly benefit future optical communication. Further, the epitaxial semiconductor structures emitting visible light can be placed on a transparent substrate or a plastic substrate. Thereby, the light emitted is easy to penetrate. Furthermore, after the nanostructures are separated from the semiconductor substrate, the semiconductor substrate can be reused, and the material cost is greatly reduced. Moreover, the semiconductor material can be placed on a non-conductive transparent substrate, a non-conductive plastic substrate, or another flexible substrate. Thereby are fabricated flex-electronics circuits and flex-optoelectronics components, displays and solar cells.

The embodiments described above are only to exemplify the present invention but not to limit the scope of the present invention. Therefore, any equivalent modification or variation according to the spirit of the present invention is to be also included within the scope of the present invention, which is based on the claims stated below.

What is claimed is:

1. A method for transferring a one-dimensional micro/nanostructure, comprising steps:
providing a first substrate having a plurality of one-dimensional micro/nanostructures;
providing a second substrate, and coating a first curable adhesive on said second substrate;
inserting said one-dimensional micro/nanostructures on said first substrate into said first curable adhesive on said second substrate;
curing said first curable adhesive; and
separating said one-dimensional micro/nanostructures from said first substrate and transferring said one-dimensional micro/nanostructures to said second substrate.

2. The method for transferring a one-dimensional micro/nanostructure according to claim 1, wherein said one-dimensional micro/nanostructures are wire-like/column-like micron/nanometric structures.

3. The method for-transferring a one-dimensional micro/nanostructure according to claim 2, wherein said one-dimensional micro/nanostructures have a width of between 1 nm and 1000 μm.

4. The method for transferring a one-dimensional micro/nanostructure according to claim 2, wherein said one-dimensional micro/nanostructures have a height of between 0.3 μm and 60 μm.

5. The method for transferring a one-dimensional micro/nanostructure according to claim 1 further comprising a step of forming said one-dimensional micro/nanostructures on said first substrate before providing said first substrate.

6. The method for transferring a one-dimensional micro/nanostructure according to claim 5, wherein said one-dimensional micro/nanostructures are formed to be vertical to said first substrate.

7. The method for transferring a one-dimensional micro/nanostructure according to claim 5, wherein said one-dimensional micro/nanostructures are formed with a CVD (Chemical Vapor Deposition) method, an epitaxial method, a chemical etching method, or a dry etching method.

8. The method for transferring a one-dimensional micro/nanostructure according to claim 1, wherein said first curable adhesive is a sol, a gel, a polymeric material, or a molten metal.

9. The method for transferring a one-dimensional micro/nanostructure according to claim 1 further comprising a step of coating a second curable adhesive on said one-dimensional micro/nanostructures before inserting said one-dimensional micro/nanostructures into said first curable adhesive.

10. The method for transferring a one-dimensional micro/nanostructure according to claim 9, wherein said second curable adhesive is a sol, a gel, a polymeric material, or a molten metal.

11. The method for transferring a one-dimensional micro/nanostructure according to claim 1, wherein said first substrate is made of a semiconductor, a metal, or an insulating material.

12. The method for transferring a one-dimensional micro/nanostructure according to claim 1, wherein said second substrate is made of a plastic, a metal, a semiconductor, a ceramic, a transparent material, or a glass coated with a transparent conductive layer.

13. The method for transferring a one-dimensional micro/nanostructure according to claim 1, wherein said first substrate are separated from said one-dimensional micro/nanostructures via ultrasonic vibration, pump suction, chemical etching, knocking a lateral side, slightly knocking a surface, or directly lifting off said first substrate.

14. The method for transferring a one-dimensional micro/nanostructure according to claim 5 further comprising a step of forming a selectively-etched layer in between said first substrate and said one-dimensional micro/nanostructures before forming said one-dimensional micro/nanostructures on said first substrate.

15. The method for transferring a one-dimensional micro/nanostructure according to claim 14, wherein said selectively-etched layer is removed with a chemical etching method to separate said one-dimensional micro/nanostructures from said first substrate and transfer said one-dimensional micro/nanostructures to said second substrate.

16. The method for transferring a one-dimensional micro/nanostructure according to claim 1 further comprising steps:
coating a welding material on a third substrate, wherein said welding material can fuse with said one-dimensional micro/nanostructures;
letting said one-dimensional micro/nanostructures on said second substrate contact said welding material on said third substrate;
heating said welding material and said one-dimensional micro/nanostructures to fuse together said welding material and said one-dimensional micro/nanostructures;
letting said welding material and said one-dimensional micro/nanostructures cool down and solidify; and
separating said one-dimensional micro/nanostructures from said second substrate and transferring said one-dimensional micro/nanostructures to said third substrate.

17. The method for transferring a one-dimensional micro/nanostructure according to claim 16, wherein said welding material and said one-dimensional micro/nanostructures are fused with a laser light, and said laser light is controlled to such an intensity that said third substrate maintains at a solid state.

18. The method for transferring a one-dimensional micro/nanostructure according to claim 16, wherein said welding material is a semiconductor material.

19. The method for transferring a one-dimensional micro/nanostructure according to claim 16, wherein said third substrate is made of a plastic, a metal, a semiconductor, a ceramic, a transparent material, or a glass coated with a transparent conductive layer.

20. The method for transferring a one-dimensional micro/nanostructure according to claim 16 further comprising a step of removing said first curable adhesive after separating said one-dimensional micro/nanostructures from said second substrate.

21. The method for transferring a one-dimensional micro/nanostructure according to claim 20, wherein said first curable adhesive is removed with a solvent.

22. The method for transferring a one-dimensional micro/nanostructure according to claim 1 further comprising steps:
removing a top surface of said first curable adhesive with a chemical etching method or a dry etching method to reveal tops of said one-dimensional micro/nanostructures from said first curable adhesive;
melting said tops of said one-dimensional micro/nanostructures with an intense laser light to form a liquid film;
letting said liquid and said one-dimensional micro/nanostructures fuse together and then cool down and solidify;
bonding said liquid film, which has solidified, to a third substrate; and
removing said first curable adhesive on said second substrate to separate said one-dimensional micro/nanostructures from said second substrate and transfer said one-dimensional micro/nanostructures to said third substrate.

23. The method for transferring a one-dimensional micro/nanostructure according to claim 22, wherein said third substrate is made of a plastic, a metal, a semiconductor, a ceramic, a transparent material, or a glass coated with a transparent conductive layer.

24. The method for transferring a one-dimensional micro/nanostructure according to claim 22, wherein said liquid film, which has solidified, is bonded to said third substrate with a van der walls force technology, a silicon-glass anodic bonding technology, a liquid-solid alloying bonding technology, or one of common LCD (Liquid Crystal Display) bonding technologies, including a TAB (Tape Automated Bonding) method, an ACF (Anisotropic Conductive Film) method, a COG (Chip On Glass) method, and a COF (Chip On Film) method.

25. The method for transferring a one-dimensional micro/nanostructure according to claim 22, wherein said first curable adhesive on said second substrate is removed with a solvent.

26. The method for transferring a one-dimensional micro/nanostructure according to claim 22 further comprising steps:
coating a third curable adhesive on a third substrate;
inserting said one-dimensional micro/nanostructures on said second substrate into said third curable adhesive on said third substrate;
curing said third curable adhesive; and
separating said second substrate from said one-dimensional micro/nanostructures and transferring said one-dimensional micro/nanostructures to said third substrate.

27. The method for transferring a one-dimensional micro/nanostructure according to claim 1 further comprising steps:
coating a welding material film on a third substrate;
letting said one-dimensional micro/nanostructures, which have been transferred to said second substrate, contact said welding material film on said third substrate;
melting said welding material film on said third substrate and said tops of said one-dimensional micro/nanostructures with an intense laser light to form a liquid film;
letting said liquid film and said one-dimensional micro/nanostructures cool down to solidify and fuse together, and separating said liquid film from said third substrate;
bonding said liquid film, which has solidified, to a fourth substrate; and
removing said first curable adhesive on said second substrate to separate said second substrate from said one-dimensional micro/nanostructures and transfer said one-dimensional micro/nanostructures to said fourth substrate.

28. The method for transferring a one-dimensional micro/nanostructure according to claim 27, wherein said third substrate is made of a plastic, a metal, a semiconductor, a ceramic, a transparent material, or a glass coated with a transparent conductive layer.

29. The method for transferring a one-dimensional micro/nanostructure according to claim 27, wherein said liquid film, which has solidified, is bonded to said third substrate with a van der walls force technology, a silicon-glass anodic bonding technology, a liquid-solid alloying bonding technology, or one of common LCD (Liquid Crystal Display) bonding technologies, including a TAB (Tape Automated Bonding) method, an ACF (Anisotropic Conductive Film) method, a COG (Chip On Glass) method, and a COF (Chip On Film) method.

30. The method for transferring a one-dimensional micro/nanostructure according to claim 27, wherein said first curable adhesive on said second substrate is removed with a solvent.

31. The method for transferring a one-dimensional micro/nanostructure according to claim 1 further comprising steps:
coating a welding material film on a third substrate, wherein said welding material can fuse with said one-dimensional micro/nanostructures;
heating and melting said welding material film;
inserting said one-dimensional micro/nanostructures on said second substrate into said welding material film on said third substrate;
letting said welding material film cool down and solidify; separating said third substrate from said welding material film to make said welding material film only bonded to said one-dimensional micro/nanostructures;
bonding said welding material film to a fourth substrate; and
separating said second substrate from said one-dimensional micro/nanostructures and transferring said one-dimensional micro/nanostructures to said fourth substrate.

32. The method for transferring a one-dimensional micro/nanostructure according to claim 1, wherein said one-dimensional micro/nanostructures is made of silicon, germanium, gallium arsenide, indium phosphide, germanium phosphide, antimony selenide, indium gallium nitride, a binary compound semiconductor, a ternary compound semiconductor, or a quaternary compound semiconductor.
